(19) United States
(12) Patent Application Publication
(10) Pub. No.: US 2010/0091462 A1
(43) Pub. Date: Apr. 15, 2010

(54) ELECTRONIC DEVICE-MOUNTED APPARATUS AND NOISE SUPPRESSION METHOD FOR SAME

(75) Inventors: Masaharu Imazato, Minato-ku (JP); Masayasu Ono, Chuo-ku (JP); Naoto Yamazaki, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, TOKYO (JP)

(21) Appl. No.: 12/527,320

(22) PCT Filed: Feb. 13, 2008
(86) PCT No.: PCT/JP2008/052366

§ 371 Date: Aug. 14, 2009

(30) Foreign Application Priority Data
Feb. 15, 2007 (JP) 2007-035124

(51) Int. Cl. H05K 7/20

(52) U.S. Cl. 361/709

(57) ABSTRACT

A noise electric current flowing through a heat sink is efficiently discharged to the ground of a printed circuit board to reduce levels of clock signal harmonic noises generated from the heat sink. An electronic device-installed apparatus is provided with a printed circuit board (1), one or more of electronic devices (2, 3) that are mounted on the printed circuit board (1) and that operate in accordance with a clock signal, and a heat sink means set to hold the electronic devices (2, 3) together with the printed circuit board (1). The heat sink means (5) is connected with the ground of the printed circuit board (1) through a connecting unit (6) and a plurality of dielectric components (12), which are independent of the electronic devices (2, 3), are provided between portions of the printed circuit board except those on which the electronic devices (2, 3) are mounted and the heat sink means (5).

### TECHNICAL FIELD

The present invention relates to an electronic device-mounted apparatus. In particular, the present invention relates to an electronic device-mounted apparatus that is provided with electronic devices such as LSI that operate according to a clock signal, and a heat radiator provided on the electronic devices for dispersing heat that is generated by the operating current of the electronic devices. The present invention further relates to a noise suppression method for avoiding the propagation of clock signal harmonic noise in the heat radiator and the radiation of noise from the heat radiator.

### BACKGROUND ART

An electronic device such as LSI that is composed of a single chip, that carries out the functions of main memory, control, and arithmetic operations, and that is used in an information processing apparatus such as a personal computer or work station requires large current in order to realize high-speed processing capabilities. A heat radiator means was implemented in electronic devices of the related art to keep the temperature from exceeding the permissible temperature of the electronic device due to heat resulting from this large current. In the present specification, “electronic device” refers to a semiconductor finished-product having a package construction and not to a semiconductor bare chip.

Regarding the background art, FIG. 1 is a top view showing an electronic device-mounted apparatus that has a heat radiator means, and FIG. 2 is a sectional view taken along line A-A′ of FIG. 1.

As shown in FIGS. 1 and 2, electronic devices 2 and 3 such as LSI having high heat generation are mounted on printed board 1. Heat-conduction sheet 4 for radiating the heat that results from the operation of electronic devices 2 and 3 is then installed over electronic devices 2 and 3.

When electronic devices 2 and 3 are operated by a clock signal, the clock signal has frequency components of a fundamental wave and a harmonic that is an integer multiple of the fundamental wave. The clock signal harmonic is propagated in printed board 1 and radiator plate 5 as noise. At such times, the noise current of the clock signal harmonic flows in radiator plate 5, but due to ground connection lines 6 that connect the ground circuit of printed board 1 and radiator plate 5, this noise current flows to the ground circuit of printed board 1. As a result, the radiation of clock signal harmonic noise from radiator plate 5 is suppressed.

As another example of the suppression of noise radiation, JP-A-H06-037512 (hereinbelow referred to as Patent Document 1) discloses a construction in which a microstrip line substrate is secured onto a radiator plate, a case composed of metal is attached to the microstrip line substrate, and the hollow portion formed by the microstrip line substrate and case is filled with resin.

In addition, JP-A-H05-315470 (hereinbelow referred to as Patent Document 2) discloses a construction that is a multichip module in which a plurality of semiconductor bare chips are packaged on a substrate and sealed by an insulating layer, wherein a metallic layer is formed on the insulating layer as a heat radiator means and the metallic layer is connected to a ground layer of the substrate. In this Patent Document 2, a structure in which an insulating layer is interposed between the metallic layer and ground layer of the substrate acts as a capacitor component and is able to reduce the power supply-ground noise.

The problem that the present invention seeks to solve is next described.

FIG. 3 shows a circuit model diagram for explaining the path of noise current in the electronic device-mounted apparatus shown in FIGS. 1 and 2. As shown in this figure, in the prior art, a plurality of electronic devices 2 and 3 are installed on printed board 1, radiator plate 5 is installed so as to cover the upper portions of all electronic devices, and ground connection lines 6 are connected between radiator plate 5 and the ground circuit of printed board 1 to suppress noise radiation from radiator plate 5.

In this configuration, clock signal harmonic noise that flows to the ground of printed board 1 flows to radiator plate 5 by way of ground connection lines 6, thereby raising the potential for noise superposition. Accordingly, the inventors of the present invention investigated electrically connecting capacitors 7 between radiator plate 5 and each of electronic devices 2 and 3 such that noise current that has flowed from ground connection lines 6 to radiator plate 5 flows to the ground of printed board 1.

FIG. 4 shows the configuration of these capacitors. Ground layer 10 that is provided on an interposed substrate of an electronic device such as SiP (System-in-Package) serves as the electrode of one side of capacitors 7. Mold 11 that is the sealant of this type of electronic device is layered on the upper layer of ground layer 10, and heat-conductive sheet 4 and radiator plate 5 are successively layered over this mold 11. Radiator plate 5 serves as the electrode of the other side of the capacitor.

Capacitance C of the capacitor formed as shown in FIG. 4 can be found from:

C=∈₀∈rA/d [Formula 1]

In this case, ∈₀ is the dielectric constant of free space, ∈r is the relative permittivity of the dielectric between the electrodes, A is the area that is found from dimensions a and b, and d is the distance between the two electrodes. For example, it will be assumed that the dimensions of electronic device 2 shown in FIG. 1 are a=25 mm and b=20 mm and that the dimensions of electronic device 3 are a=11 mm and b=11 mm, that the distance between the electrodes of each of electronic devices 2 and 3 is 2 mm, and that the permittivity of mold 11 and heat conduction sheet 4 is 4.4. The capacitance of the capacitor formed at electronic device 2 is therefore approximately 9700 pF and the capacitance of the capacitors formed at electronic devices 3 is approximately 2400 pF.

The capacitors having these capacitances are formed between radiator plate 5 and printed board 1 as capacitors 7 shown in FIG. 3. Accordingly, the noise current from ground connection line 6 that is noise source 8 flows by way of capacitors 7 formed on each of electronic devices 2 and 3 and the other ground connection line 6 to the ground of printed board 1. To illustrate this flow, FIG. 3 shows noise source 8 provided on ground connection line 6, and noise current paths 9 that flow from noise source 8 by way of radiator plate 5.

However, the flow of a portion of the noise current that flows through radiator plate 5 shown above to surfaces other than the printed board 1 side of radiator plate 5 raises the concern that noise will be superposed upon devices that are packaged by this electronic device mounting apparatus due to the strong magnetic field from radiator plate 5. Alternatively, the concern also exists that the specified noise range that applies to this device will not be satisfied due to the occurrence of, for example, noise radiation from the device.

In order to limit the strong magnetic field caused by the noise current that flows through this radiator plate, nearly all of the noise current that flows to the radiator plate must be caused to flow to the ground of the printed board.

### DISCLOSURE OF THE INVENTION

It is an object of the present invention to provide an electronic device-mounted apparatus and a noise suppression method that can solve at least one of the above-described problems. An example of this object is to effectively cause noise current that flows to a radiator plate for dissipating the heat of an electronic device to flow to the ground of a printed board and thus reduce the level of the clock signal harmonic noise that is radiated from the radiator plate.

One mode of the present invention relates to an electronic device-mounted apparatus that includes: a printed board, one or a plurality of electronic devices that are mounted on the printed board and that operate by a clock signal, and a radiator means provided such that the electronic devices are interposed between the printed board and the radiator means.

In this apparatus, the above-described object can be realized by providing: connectors for connecting the radiator means and the ground of the printed board; and dielectric components that are independent of the electronic devices and that are interposed between the radiator means and the printed board at positions other than locations where the electronic devices are mounted.

In the construction disclosed in Patent Document 1, noise radiation from micro-strip lines is suppressed by a resin, and no configuration is disclosed in which noise current that flows in a radiator plate is caused to flow to the ground of a printed board.

Cited Reference 2 only vaguely describes the object of eliminating noise between the power supply and ground, and makes absolutely no disclosures regarding the points of the propagation of clock signal harmonic of an electronic device to a radiator plate and the avoidance of the radiation of the clock signal harmonic noise from the radiator plate. Still further, the configuration disclosed in Cited Reference 2 is a construction in which an insulating material that is a dielectric is packed to cover a plurality of semiconductor bare chips without gaps between a metallic layer that is a radiator means and a printed board. In other words, Cited Reference 2 is not a technique for using dielectric components, that are independently arranged between a radiator plate and a printed board, to actively cause the noise current of the clock signal harmonic that flows to the radiator plate to return toward the ground of the printed board and thus reduce noise radiation from the radiator plate. In addition, Cited Reference 2 is not an invention relating to an electronic device-mounted apparatus in which a semiconductor finished-product such as an LSI package is mounted.

### BRIEF DESCRIPTION OF THE DRAWINGS

FIG. 1 is a top view showing an electronic device-mounted apparatus as an example of the background art;

FIG. 2 is a sectional view taken along line A-A of FIG. 1;

FIG. 3 is a circuit model diagram of the electronic device-mounted apparatus that models the problem that the present invention is intended to solve;

FIG. 4 is a perspective view showing the construction of capacitors that were investigated in the apparatus of FIG. 1;

FIG. 5 is a top view of the electronic device-mounted apparatus that relates to the first embodiment of the present invention;

FIG. 6 is a sectional view taken along line A-A of FIG. 5;

FIG. 7 is a perspective view of a dielectric component relating to the first embodiment of the present invention;

FIG. 8 is a view for comparing the actually measured data of near magnetic field distribution characteristics on a radiator plate;

FIG. 9 is a view for comparing electromagnetic field simulation data for near magnetic field distribution characteristics of 800-MHz on a radiator plate;

FIG. 10 is a view for comparing electromagnetic field simulation data for near magnetic field distribution characteristics of 1066-MHz on a radiator plate;

FIG. 11 is a view for comparing electromagnetic field simulation data for near magnetic field distribution characteristics of 1333-MHz on a radiator plate;

FIG. 12 is a circuit model diagram of an electronic device-mounted apparatus relating to the first embodiment;

FIG. 13 is a top view of an electronic device-mounted apparatus that relates to the second embodiment of the present invention;

FIG. 14 is a sectional view taken along line A-A of FIG. 15;

FIG. 15 is a top view of an electronic device-mounted apparatus that relates to the third embodiment of the present invention;

FIG. 16 is a sectional view taken along line A-A of FIG. 15; and

FIG. 17 is a perspective view of a dielectric component that relates to the fourth embodiment of the present invention.

### BEST MODE FOR CARRYING OUT THE INVENTION

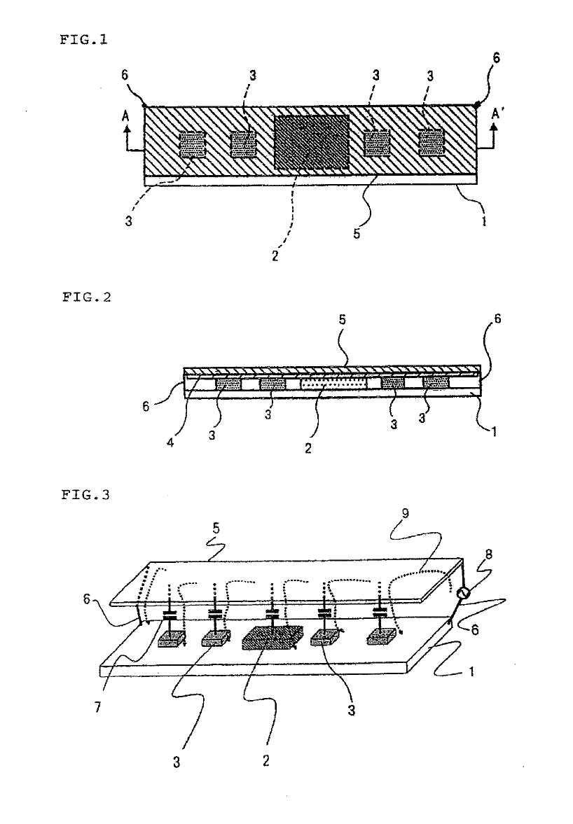

Details of the embodiments of the present invention are next described with reference to the accompanying figures. Constituent elements that are identical to the configurations shown in FIGS. 1 and 2 are described using the same reference numbers.

### First Embodiment

FIG. 5 is a top view of the electronic device-mounted apparatus that relates to the first embodiment of the present invention, and FIG. 6 is a sectional view taken along line A-A′ of FIG. 5. As shown in FIG. 5 and FIG. 6, electronic devices 2 and 3 that operate by a clock signal are mounted on printed board 1. In the present example, electronic devices 2 and 3 have mutually different planar shapes. Although no particular limitations apply, the shapes of electronic devices 2 and 3 are, for example, semiconductor finished-products such as System-in-Package (SiP) in which one or a plurality of LSI bare chips are mounted on a package substrate with an interposer substrate interposed and which are sealed by an insulating material.

Heat-conductive sheet 4 and radiator plate 5 are stacked in that sequence over electronic devices 2 and 3 and thus rest on electronic devices 2 and 3. In other words, electronic devices 2 and 3 are interposed between printed board 1 and radiator plate 5. In the present example, moreover, the longitudinal dimensions of radiator plate 5 and printed board 1 are made substantially equal, and radiator plate 5 and the ground of printed board 1 are connected by means of ground connection lines 6 at the two ends in the longitudinal direction of radiator plate 5 and printed board 1.

Columnar dielectric components 12 are arranged between radiator plate 5 and printed board 1 at locations other than electronic devices 2 and 3 to electrically connect the ground of printed board 1 and radiator plate 5. Dielectric component 12 has substantially the same shape as the planar shape of electronic device 3, and a plurality of dielectric components 12 are arranged on printed board 1 from the ends at which ground connection lines 6 are connected to as far as the location of the installation of electronic device 2. In the present example, a plurality of dielectric components 12 and electronic devices 2 and 3 are arranged at substantially equal spacing over substantially the entire surface of the electronic device side of radiator plate 5.

Dielectric component 12 is a construction in which dielectric 14 of a predetermined shape is mounted on conductive plate 13 as shown in FIG. 7. Dielectric component 12 is secured by connecting conductive plate 13 of the bottom surface to the ground of printed board 1. Radiator plate 5 is then connected by way of heat-conductive sheet 4 to the surface of dielectric 14 that is opposite the conductive plate 13 side. In this way, capacitors are formed that electrically connect radiator plate 5 and the ground of printed board 1 at each of the sites at which dielectric 14 is placed. The planar shape of dielectric component 12 in this embodiment is a rectangle, but the planar shape may be another shape such as an oval. In addition, the plurality of dielectric components 12 that are arranged between printed board 1 and radiator plate 5 need not all be the same shape.

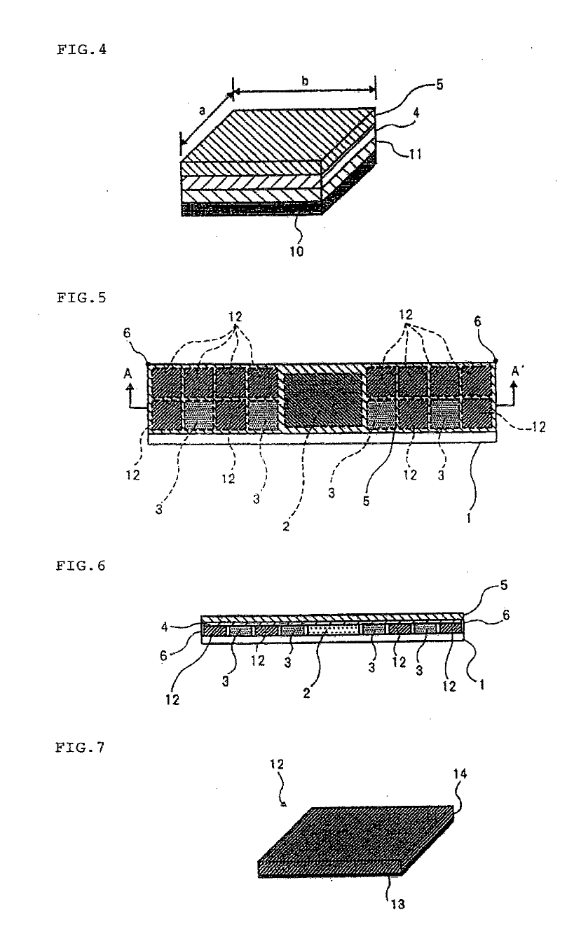

As in the configuration shown in FIG. 4, capacitors are also formed between radiator plate 5 and each of electronic devices 2 and 3.

According to the above configuration, the noise current of the clock signal harmonic that results from the operation of electronic devices 2 and 3 flows from the ground of printed board 1 to radiator plate 5 by way of ground connection lines 6. A plurality of capacitors formed by electronic devices 2 and 3 and a plurality of dielectric components 12 at a plurality of locations between radiator plate 5 and printed board 1 are interposed over substantially the entire surface of radiator plate 5, whereby nearly all noise current that flows over radiator plate 5 flows to the ground of printed board 1 and noise radiation from the surface of radiator plate 5 that is opposite that of the electronic device-side can be suppressed.

The plurality of dielectric components 12 are preferably arranged at locations that are as close as possible to the ends of radiator plate 5 to which ground connection lines 6, that are noise sources, are connected, rather than being arranged close to locations where electronic devices 2 and 3 are mounted. This is because paths can be secured in areas that are closer to the noise source for actively returning, to the ground of printed board 1, the noise current that flows from the noise sources to radiator plate 5.

The radiation noise suppression effect realized by the present embodiment is next described based on FIGS. 8 to 11.

FIG. 8 shows the results of measuring the near magnetic field of the surface of radiator plate 5 that is opposite the electronic devices when the harmonic frequency of the clock signal is 800 MHz. FIG. 8(a) shows the near magnetic field distribution on the surface of the radiator plate that is opposite the electronic device side that relates to the electronic device-mounted apparatus shown in FIG. 1, and FIG. 8(b) shows the near magnetic field distribution on the surface of the radiator plate that is opposite that of the electronic devices that relates to the electronic device-mounted apparatus of the present embodiment. In contrast to the radiator plate according to the background art in which a strong field, that results from the noise current that flows in the surface opposite the electronic device side, can be confirmed, it can be seen that in the radiator plate of the present embodiment, the noise current that flows in the surface opposite the electronic device side is low and that the magnetic field strength is reduced.

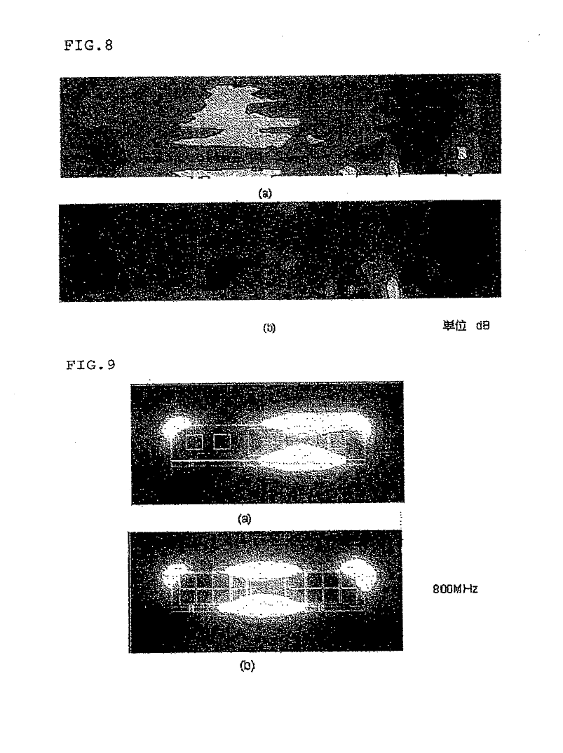

Next, FIGS. 9, 10, and 11 show the results of carrying out electromagnetic field simulations of the surface of radiator plate that is opposite the electronic device side with the harmonic of the clock signal at 800 MHz, 1066 MHz, and 1333 MHz. In these figures, the distribution of strength is represented in which the stronger magnetic field strength is shown as lighter and in which the reduced magnetic field strength is shown as darker.

FIG. 9 shows the near magnetic field distribution when the harmonic of the clock signal is 800 MHz, FIG. 9(a) showing the near magnetic field distribution of the surface of the radiator plate that is opposite the electronic device side relating to the electronic device-mounted apparatus of the background art, and FIG. 9(b) showing the near magnetic field distribution of the surface of the radiator plate that is opposite the electronic device side relating to the electronic device-mounted apparatus of the present embodiment. It can be seen from the figures that strong fields that are shown by the white areas are broader in FIG. 9(a) that shows the device of the background art.

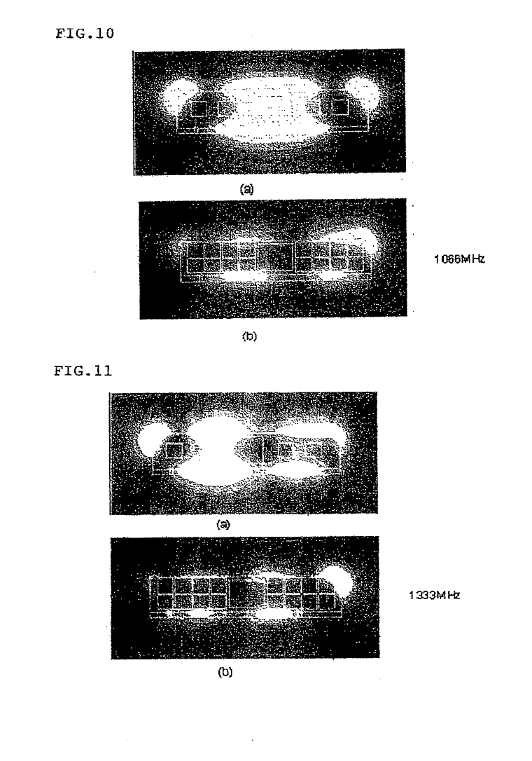

FIG. 10 shows the near magnetic field distribution when the harmonic of the clock signal is 1066 MHz, FIG. 10(a) showing the near magnetic field distribution of the surface of the radiator plate that is opposite the electronic device side relating to the electronic device-mounted apparatus of the background art, and FIG. 10(b) showing the near magnetic field distribution of the surface opposite the electronic device side of the radiator plate relating to the electronic device-mounted apparatus of the present embodiment. It can be seen from the figures that the strong fields that are shown by the white areas are broader in FIG. 10(a) that shows the device of the background art.

FIG. 11 shows the near magnetic field distribution when the clock signal harmonic is 1333 MHz, FIG. 11(a) showing the near magnetic field distribution on the surface of the radiator plate that is opposite the electronic device side relating to the electronic device-mounted apparatus of the background art, and FIG. 11(b) showing the near magnetic field distribution of the surface opposite of the radiator plate that is the electronic device side relating to the electronic device-mounted apparatus of the present embodiment. It can be seen from the figures that the strong fields that are shown by the white areas are broader in FIG. 11(a) that shows the device of the background art.

Based on the results of the near magnetic field distribution according to the actually measured data of FIG. 8 and the electromagnetic field simulations of FIGS. 9-11, it can be seen that the magnetic field strength on the surface side of radiator plate 5 is more greatly reduced by the configuration of the present embodiment than in the prior art. In other words, in this embodiment, radiator plate 5 and the ground of printed board 1 are connected, and a plurality of capacitors formed by electronic devices 2 and 3 and a plurality of dielectric components 12 between printed board 1 and radiator plate 5 are arranged over substantially the entire surface of radiator plate 5. According to this construction, virtually no noise current flows in the surface of radiator plate 5 that is opposite the electronic devices and the magnetic field strength on radiator plate 5 can be reduced.

FIG. 12 shows a circuit model chart for explaining the paths of noise current in the electronic device-mounted apparatus of the present embodiment.

In FIG. 12, noise current from noise source 8 flows to radiator plate 5 by way of ground connection line 6. Capacitors C16, C17, and C18 that are formed using a plurality of dielectric components 12 are connected to each of a plurality of locations other than the locations where electronic devices are mounted between radiator plate 5 and the ground 15 of the printed board. As a result, noise current flows through noise current paths 19, 20, and 21 to ground 15 of the printed board.

At this time, noise radiation from radiator plate 5 becomes magnetic field strength proportional to the area made up by the paths of noise current. As a result, in the circuit shown in FIG. 8, by causing nearly all of the noise current on radiator plate 5 to flow to noise current path 19, noise radiation from radiator plate 5 can be more thoroughly suppressed.

Typically, impedance Z of the capacitor portion is represented by Z=1/(ωC) where ω=2πf (f being the frequency of the noise current). Accordingly, in order to actively cause noise current to flow to noise current path 19 of FIG. 12, impedance Z of capacitor C16 must be a relatively small value, i.e., capacitance C must be a large value. Capacitance C of a capacitor is obtained by means of the above-described formula 1.

In the case of electronic device-mounted apparatus shown in FIG. 5, according to formula 1, lower impedance can be realized by using a material having a larger capacitance for dielectric 14 (see FIG. 7) that constitutes dielectric component 12, and the noise current path area can also be reduced. In this way, an electronic device-mounted apparatus can be realized that exhibits a higher noise suppression effect.

In this case, a greater effect is obtained by arranging dielectric component 12 having capacitances C that increase with proximity to the locations at which ground connection lines 6 of radiator plate 5 are connected. This is because paths for actively returning noise current from ground connection lines 6 that are noise sources to the ground of printed board 1 can be guaranteed in areas close to the noise source of radiator plate 5. As a result, radiation noise (magnetic field strength) from radiator plate 5 is also reduced. Still further, when capacitors are also formed at electronic devices 2 and 3 by the configuration shown in FIG. 4, it is effective to arrange dielectric component 12 having greater effective capacitance C than electronic devices 2 and 3 at locations closer to the noise sources than electronic devices 2 and 3.

In addition, noise suppression that accords with the field strength distribution on radiator plate 5 can also be implemented in the present embodiment by using a plurality of dielectric components 12 having differing capacitances C. In other words, using a plurality of dielectric components 12 having greater capacitance C for locations at which the magnetic field strength on radiator plate 5 is relatively great can effectively reduce noise radiation from radiator plate 5.

### Second Embodiment

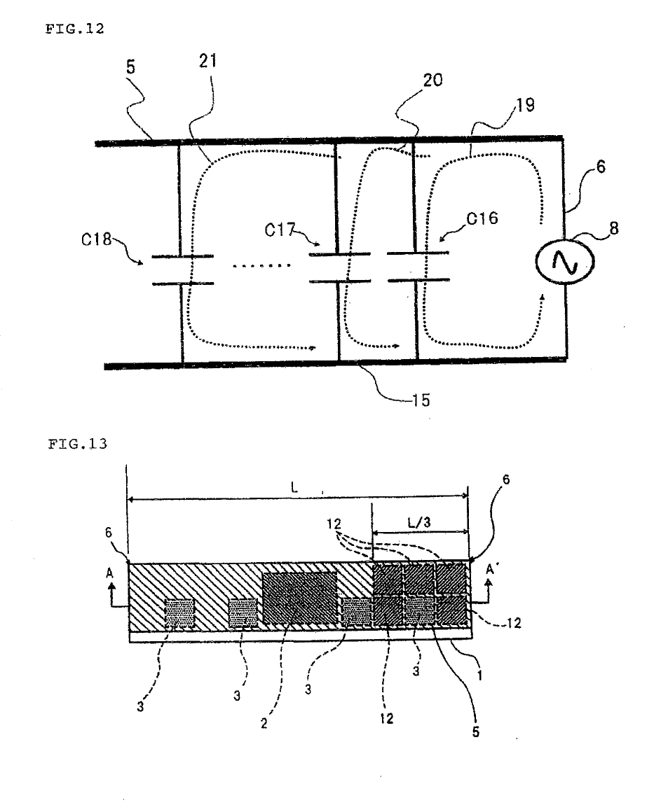

FIG. 13 is a top view of the electronic device-mounted apparatus that relates to the second embodiment of the present invention, and FIG. 14 is a sectional view taken along line A-A′ of FIG. 13.

As shown by FIGS. 13 and 14, electronic devices 2 and 3 are mounted on printed board 1, and radiator plate 5 is installed on electronic devices 2 and 3 with heat-conduction sheet 4 interposed. Still further, radiator plate 5 and the ground of printed board 1 are electrically connected by ground connection lines 6 at both ends in the longitudinal direction of printed board 1. A plurality of dielectric components 12 are arranged at a plurality of locations, that are isolated from the sites where electronic devices 2 and 3 are mounted, between radiator plate 5 and printed board 1 to electrically connect radiator plate 5 and the ground of printed board 1. Dielectric component 12 has substantially the same shape as the planar shape of electronic device 3. In addition, capacitors are formed at each position of electronic devices 2 and 3 and a plurality of dielectric components 12. This configuration is identical to that of the first embodiment. In the present embodiment, however, The plurality of dielectric components 12 are provided in areas having at least one-third the length of the longitudinal dimension L of the radiator plate from the ends of radiator plate 5 to which ground connection lines 6 are connected.

According to the above-described configuration, the noise current of the clock signal harmonic resulting from the operation of electronic devices 2 and 3 flows from the ground of printed board 1 to radiator plate 5 by way of ground connection lines 6. A plurality of capacitors formed by electronic devices 2 and 3 and a plurality of dielectric components 12 are interposed at a plurality of locations between radiator plate 5 and printed board 1 in areas of at least one-third the length of longitudinal dimension L of radiator plate from the ends of radiator plate 5 to which ground connection lines 6 are connected.

In this way, nearly all of the noise current that flows to radiator plate 5 from ground connection lines 6 that are noise sources can be actively returned to the ground of printed board 1 by the plurality of capacitors formed in one third of the above described areas on the ground connection line 6 side, and noise radiation from the surface of radiator plate 5 that is opposite the electronic device side can be suppressed.

For this purpose, a plurality of dielectric components 12 are more preferably arranged at positions that are as close as possible to the ends of radiator plate 5 to which ground connection lines 6, that are noise sources, are connected, rather than being arranged close to locations where electronic devices 2 and 3 are mounted. The reason for this is that many paths can be guaranteed in areas that are closer to the noise sources for actively returning, to the ground of printed board 1, the noise current that has flowed to radiator plate 5 from the noise sources. As in the first embodiment, noise suppression according to the position (magnetic field distribution) on radiator plate 5 can be realized by means of the plurality of capacitors that are formed between radiator plate 5 and printed beard 1.

### Third Embodiment

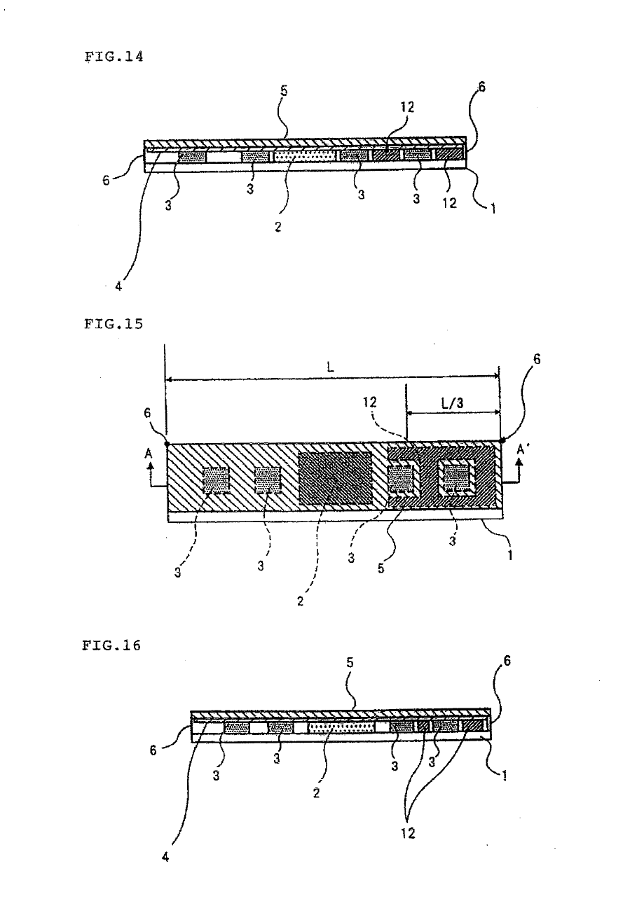

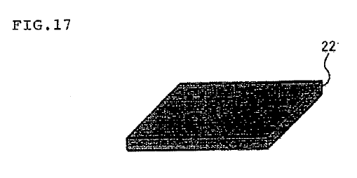

FIG. 15 is a top view of the electronic device-mounted apparatus that relates to the third embodiment of the present invention, and FIG. 16 is a sectional view taken along line A-A′ of FIG. 15. Because the form shown in these figures is a modification of the second embodiment, only points of difference will be described.

In the present embodiment, one dielectric component 12 is interposed between printed board 1 and radiator plate 5 in an area having a length that is at least one-third of radiator plate longitudinal dimension L from the end of radiator plate 5 to which ground connection line 6 is connected. This dielectric component 12 is composed of a frame shape that encloses electronic device 3 on printed board 1 with spacing interposed, as shown in by the dotted lines in FIG. 15.

In this embodiment as well, nearly all of the noise current that flows to radiator plate 5 from ground connection line 6 that is a noise source can be actively returned to the ground of printed board 1 by means of the capacitor formed in the above-described L/3 area on ground connection line 6 side to enable suppression of noise radiation from the surface of radiator plate 5 that is opposite the electronic device side.

### Fourth Embodiment

FIG. 17 is a perspective view of the dielectric component that relates to the fourth embodiment of the present invention.

In the previously described first to third embodiments, components composed of a dielectric and conductive plates as shown in FIG. 7 were used as dielectric component 12. However, capacitors can be configured between printed board 1 and radiator plate 5 of each of the embodiments even when dielectric component 12 of this configuration is not used. For example, in some cases, a ground pattern is formed in portions of the surface layer of printed board 1 other than the sites for mounting electronic devices. In such cases, dielectric component made up of only dielectric 22 as shown in FIG. 17 is installed on the ground pattern. Radiator plate 5 is then connected to the surface of dielectric 22 that is opposite the ground pattern side with heat-conductive sheet 4 interposed. In this way, capacitors that electrically connect radiator plate 5 and the ground of printed board 1 are formed at each of the positions in which dielectric 22 is installed. In other words, the ground pattern of the surface layer of printed board 1 serves as the electrode of one side of a capacitor unit and radiator plate 5 serves as the electrode of the other side.

Accordingly, dielectric component that is made up from only dielectric can be applied in each of the above-described embodiments. In addition, the planar shape of a dielectric component in the present embodiment was rectangular, but other shapes such as an oval may also be used.

### Other Embodiments of the Present Invention

The electronic device-mounted apparatus of the present invention that was described by taking the embodiments as examples is an apparatus arranged such that electronic devices are interposed between a printed board and a radiator means. This apparatus is provided with: connectors for connecting the radiator means and the ground of the printed board, and dielectric components that are interposed between the printed board and radiator means at sites other than the mounting sites of electronic devices. These dielectric components are components arranged to be isolated from the electronic devices.

The following points can be taken as another embodiment of this invention.

Another embodiment is an electronic device-mounted apparatus provided with: connectors for connecting the above-described radiator means and ground of a printed board at the longitudinal end portions of the radiator means; and dielectric components interposed between the printed board and the radiator means at positions that are isolated from the sites where electronic devices are mounted. This apparatus is characterized by the provision of dielectric components in areas having one-third the length of the longitudinal dimension of the radiator means from the longitudinal end portions of the radiator means to which the connectors are connected.

In this embodiment, the dielectric components preferably have substantially the same shape as the electronic devices or have a frame shape that encloses the electronic devices.

Still further, the above-described dielectric components are preferably made up from a dielectric having a predetermined shape and a conductive plate installed on the bottom surface of the dielectric, and the conductive plate preferably is connected to the ground of the printed board.

Another embodiment is an electronic device-mounted apparatus characterized by the interposition of the dielectric that makes up the above-described dielectric components between a ground pattern formed on the surface layer of the printed board and the radiator means. In this embodiment as well, the dielectric components preferably have substantially the same shape as the electronic devices, or have frame shapes that enclose the electronic devices.

In another embodiment such as described above, a plurality of dielectric components is preferably provided, and the capacitance C of each of the dielectric components preferably differs according to the magnetic field distribution of the radiator means. In this case, the plurality of dielectric components preferably have capacitances C that increase with greater proximity to the sites of the radiator means at which the connectors are connected.

Another embodiment is a noise suppression method of an electronic device-mounted apparatus that includes: a printed board, one or a plurality of electronic devices that are mounted on the printed board and that operate according to a clock signal, and a radiator means provided such that the electronic devices are interposed between the printed board and the radiator means. This method is characterized by: connecting the radiator means and the ground of the printed board, and interposing a plurality of dielectric components between the printed board and the radiator means in positions that are isolated from the sites where the electronic devices are mounted to suppress the radiation of noise from the side of the radiator means that is opposite the printed board.

In each of the embodiments described hereinabove, not only are the radiator means and the ground of the printed board connected, but the radiator plate and printed board are also connected by dielectric components over a plurality of sites that are isolated from the sites where the electronic devices are mounted. As a result, nearly all of the noise current of the clock signal harmonic that has flowed to the radiator means from the printed board and through the connectors can be returned to the ground of the printed board by the dielectric components. In this way, the radiation of clock signal harmonic noise from the radiator means can be suppressed to a low level.

Thus, according to the present invention, clock signal harmonic noise that is propagated to the radiator means from electronic devices that operate according to a clock signal and that is radiated from the radiator means can be decreased. In other words, the strength of the magnetic field that is generated from the radiator means of an electronic device-mounted apparatus can be reduced to a low level.

Although described hereinabove with regard to embodiments of the present invention, the invention of the present application is not limited to the above-described embodiments and is of course open to various modifications that do not depart from the spirit or scope of the invention.

This application claims priority based on Japanese Patent Application 2007-035124 for which application was submitted on Feb. 15, 2007 and incorporates all disclosures of that invention.

1. An electronic device-mounted apparatus comprising:
a printed board;
one or a plurality of electronic devices that are mounted on the printed board and that operate by a clock signal;
a radiator means provided such that said electronic devices are interposed between said printed board and said radiation means;
connectors for electrically connecting said radiator means and the
ground of said printed board; and
a dielectric component that is independent of said electronic devices and that is interposed between said radiator means and said printed board at a position other than locations where said electronic devices are mounted.

2. The electronic device-mounted apparatus according to claim 1, wherein:
said connectors electrically connect said radiator means and the ground of said printed board at the longitudinal end portions of said radiator means;
and
said dielectric component is provided in an area having a length of one third the longitudinal length of said radiator means from a longitudinal end portion of said radiator means at which said connector is connected.

3. The electronic device-mounted apparatus according to claim 2, wherein said dielectric component has a shape that is substantially identical to that of said electronic devices.

4. The electronic device-mounted apparatus according to claim 2, wherein said dielectric component has a frame shape that encloses said electronic devices.

5. The electronic device-mounted apparatus according to claim 1, wherein said dielectric component is composed of a dielectric having a predetermined shape and a conductive plate installed on the bottom surface of the dielectric, and wherein the conductive plate is connected to the ground of said printed board.

6. The electronic device-mounted apparatus according to claim 1, wherein the dielectric that makes up said dielectric component is interposed between a ground pattern that is formed on the surface layer of said printed board and said radiator means.

7. The electronic device-mounted apparatus according to claim 6, wherein said dielectric component has a shape substantially identical to that of said electronic devices.

8. The electronic device-mounted apparatus according to claim 6, wherein said dielectric component has a frame shape that encloses said electronic devices.

9. The electronic device-mounted apparatus according to claim 1, wherein a plurality of said dielectric components is provided, and capacitance C of each of these dielectric components differs according to the magnetic field distribution of said radiator means.

10. The electronic device-mounted apparatus according to claim 1, wherein a plurality of said dielectric components is provided, and capacitance C of dielectric components increases according to increased proximity of dielectric components to sites of said radiator means at which said connectors are connected.

11. An electronic device-mounted apparatus noise suppression method for suppressing noise of an electronic device-mounted apparatus that includes a printed board, one or a plurality of electronic devices that are mounted on the printed board and that operate by a clock signal, and a radiator means provided such that said electronic devices are interposed between said printed board and said radiator means, said method comprising steps of:
electrically connecting said radiator means and the ground of said printed board; and
interposing a plurality of dielectric components between said printed board and said radiator means at positions other than the sites where said electronic devices are mounted to suppress the radiation of noise from the side of said radiator means that is opposite said printed board.

12. The electronic device-mounted apparatus noise suppression method according to claim 11, wherein said plurality of dielectric components have capacitance C that increases with increased proximity of a dielectric component to sites of connection of said ground of said radiator means.
